(19) United States
(12) Patent Application Publication
(10) Pub. No.: US 2014/0339498 A1
(43) Pub. Date: Nov. 20, 2014

(54) RADIATION-EMITTING SEMICONDUCTOR CHIP

(71) Applicant: OSRAM OPTO SEMICONDUCTORS GMBH, Regensburg (DE)

(72) Inventors: Martin R. Behringer, Regensburg (DE); Christoph Klemp, Regensburg (DE); Ivar Tångring, Regensburg (DE); Peter Heidborn, Zeitlarn (DE)

(21) Appl. No.: 14/344,532

(22) PCT Filed: Jul. 30, 2012
(86) PCT No.: PCT/EP2012/064891

§ 371 Date: May 7, 2014

(30) Foreign Application Priority Data
Sep. 23, 2011 (DE) 10 2011 114 380.0

(51) Int. Cl. H01L 33/30; H01L 33/00; H01L 33/06

(52) U.S. Cl. CPC H01L 33/30; H01L 33/06; H01L 33/0025
USPC 257/13; 257/94

(57) ABSTRACT

A radiation-emitting semiconductor chip includes a semiconductor body with a semiconductor layer sequence, wherein the semiconductor body with the semiconductor layer sequence extends in a vertical direction between a first major face and a second major face; the semiconductor layer sequence includes an active region that generates radiation, a first region of a first conduction type and a second region of a second conduction type differing from the first conduction type; the first region extends in a vertical direction between the first major face and the active region; the second region extends in a vertical direction between the second major face and the active region; at least one layer of the active region is based on an arsenide compound semiconductor material; and relative to its respective extent in the vertical direction, the first region or the second region is based in a proportion of at least half on a phosphide compound semiconductor material.

### TECHNICAL FIELD

This disclosure relates to a radiation-emitting semiconductor chip.

### BACKGROUND

Arsenide compound semiconductor material is particularly suitable for producing luminescent diodes with an emission wavelength in the infrared spectral range. With regard to the environmental compatibility of the devices, however, it is desirable as far as possible to omit arsenic. Moreover, known infrared light-emitting diodes based on arsenide compound semiconductor material display comparatively low temperature stability, i.e. the radiant power emitted decreases comparatively steeply as the temperature of the semiconductor chip rises.

There is thus a need to provide a device that emits in the infrared spectral range which is distinguished by improved environmental compatibility and increased temperature stability.

### SUMMARY

We provide a radiation-emitting semiconductor chip including a semiconductor body with a semiconductor layer sequence, wherein the semiconductor body with the semiconductor layer sequence extends in a vertical direction between a first major face and a second major face; the semiconductor layer sequence includes an active region that generates radiation, a first region of a first conduction type and a second region of a second conduction type differing from the first conduction type; the first region extends in a vertical direction between the first major face and the active region; the second region extends in a vertical direction between the second major face and the active region; at least one layer of the active region is based on an arsenide compound semiconductor material; and relative to its respective extent in the vertical direction, the first region or the second region is based in a proportion of at least half on a phosphide compound semiconductor material.

We also provide a radiation-emitting semiconductor chip including a semiconductor body with a semiconductor layer sequence, wherein the semiconductor body with the semiconductor layer sequence extends in a vertical direction between a first major face and a second major face; the semiconductor layer sequence includes an active region that generates radiation, a first region of a first conduction type and a second region of a second conduction type differing from the first conduction type; the first region extends in a vertical direction between the first major face and the active region; the second region extends in a vertical direction between the second major face and the active region; at least one layer of the active region is based on an arsenide compound semiconductor material; and the entire first region and the entire second region are based on phosphide compound semiconductor material.

### BRIEF DESCRIPTION OF THE DRAWINGS

FIG. 1 is a schematic sectional view of an example of a multilayer structure of a semiconductor chip.

FIGS. 2 and 3 each show measurement results for the emitted intensity of the radiation emitted when a semiconductor chip is in operation, in each case as a function of the temperature of different semiconductor chips compared to conventional arsenide compound semiconductor chips.

### DETAILED DESCRIPTION

Our radiation-emitting semiconductor chips may comprise a semiconductor body with a semiconductor layer sequence. The semiconductor body extends in a vertical direction between a first major face and a second major face. The semiconductor layer sequence comprises an active region intended to generate radiation, a first region of a first conduction type and a second region of a second conduction type differing from the first conduction type. The first region extends in a vertical direction between the first major face and the active region. The second region extends in a vertical direction between the second major face and the active region. At least one layer of the active region is based on an arsenide compound semiconductor material. Relative to its respective extent in the vertical direction, the first region or the second region is based in a proportion of at least half on a phosphide compound semiconductor material.

In other words, at least half the thickness of the first region and/or of the second region is based on a phosphide compound semiconductor material. The fraction based on phosphide compound semiconductor material of the first and/or second region may be contiguous in a vertical direction or be configured as two or more sub-regions spaced from one another in a vertical direction in the first region or in the second region.

The semiconductor chip may also comprise more than one active region. In this case the first region extends between the first major face and the active region closest to the first major face. Accordingly, the second region extends between the second major face and the active region closest to the second major face.

“Based on arsenide compound semiconductor material” means in this context that a layer or a region comprises a III-V compound semiconductor material in which arsenic predominantly occupies, i.e. occupies at least 51% of, the group V lattice sites. Preferably at least 60%, particularly preferably at least 80%, of the group V lattice sites are occupied by arsenic. The compound semiconductor material may be formed in particular by the material system InₓAl_{y}Ga_{1-x-y}P_{1-z}As_{z} with 0≦x≦1, 0≦y≦1, x+y≦1 and 0.51≦z≦1, in particular with z=1.

Accordingly, “based on phosphide compound semiconductor material” means in this context that a layer or a region comprises a III-V compound semiconductor material in which phosphorus predominantly occupies, i.e. occupies at least 51% of the group V lattice sites. Preferably at least 60%, particularly preferably at least 80%, of the group V lattice sites are occupied by phosphorus. The compound semiconductor material may be formed in particular by the material system InₓAl_{y}Ga_{1-x-y}P_{1-z}As_{z} with 0≦x≦1, 0≦y≦1, x+y≦1 and 0≦z≦0.49.

A “vertical direction” means a direction which extends perpendicular to a main plane of extension of the semiconductor layers of the semiconductor layer sequence.

Therefore, compared to a conventional semiconductor material based on arsenide semiconductor material, in the first and/or the second region the arsenide semiconductor material is at least partially replaced by phosphide compound semiconductor material. The arsenic content of the semiconductor chip may be reduced in this way without any change to the peak wavelength of the emitted radiation.

The first region and second region are preferably based, relative to their respective extent in the vertical direction, in a proportion of at least half, particularly preferably at least 70%, on a phosphide compound semiconductor material.

Preferably, the phosphide compound semiconductor material may be formed by the material system InₓAl_{y}Ga_{1-x-y}P_{1-z}As_{z} with 0≦x≦0.6, 0≦y≦1, x+y≦1 and 0≦z≦0.3.

Moreover, for the arsenic content z the relationship 0≦z≦0.1, particularly preferably 0≦z≦0.05 preferably applies.

Preferably, 0.4≦x≦0.6, preferably 0.5≦x≦0.56 applies for the indium-content x of the phosphide compound semiconductor material. Phosphide compound semiconductor material, in particular arsenic-free phosphide compound semiconductor material, with an indium content in the stated region is lattice-matched or largely lattice-matched to an arsenide compound semiconductor material such that the semiconductor layer sequence of the semiconductor chip can be simply deposited with a high crystal quality.

Preferably, at most 20% of the group V lattice sites of the entire first region and/or at most 20% of the group V lattice sites of the entire second region are occupied by arsenic. The lower the arsenic content outside the active region, the more significantly the arsenic content of the semiconductor chip can be reduced, without any change to the peak wavelength of the radiation generated by the active region.

The first region and second region are preferably each of multilayer construction.

Preferably, the first region comprises a contact region adjoining the first major face. Accordingly, the second region preferably comprises a second contact region adjoining the second major face.

A barrier region is preferably formed between the contact region and the active region. Accordingly, a second barrier region is preferably formed between the second contact region and the active region.

The barrier region is preferably at least twice as thick, particularly preferably at least five times as thick, as the contact region. Even when using an arsenide compound semiconductor material for the contact region, the arsenic content of the semiconductor chip may in this way be kept low overall.

The first barrier region and the second barrier region preferably each have a larger band gap than the active region layers arranged between the barrier regions.

At least one of the barrier regions or at least one region thereof may moreover take the form of a charge carrier barrier for the opposite charge type to the conduction type of the region. That is to say, a barrier region in an n-conductive region may take the form of a hole barrier, while a barrier region in a p-conductive region may take the form of an electron barrier.

Preferably at most 10%, particularly preferably at most 5%, most preferably at most 1% of the group V lattice sites of the first barrier region and/or of the second barrier region are occupied by arsenic. Particularly preferably, the first barrier region and/or the second barrier region is/are free of arsenic. The active region may thus be adjoined on one or both sides by semiconductor layers which are free of arsenic.

Further preferably, the active region comprises a quantum well structure. “Quantum well structure” includes in particular any structure in which charge carriers may undergo quantisation of their energy states by inclusion (“confinement”). In particular, “quantum well structure” does not provide any indication of the dimensionality of the quantisation. It thus encompasses inter alia quantum troughs, quantum wires and quantum dots and any combination of these structures.

The quantum well structure preferably comprises at least one quantum layer and at least one barrier layer. In particular, the quantum well structure may comprise three to 20 quantum layers, one barrier layer preferably being arranged between every two adjoining quantum layers.

Preferably, at least one barrier layer of the quantum well structure, particularly preferably all the barrier layers of the quantum well structure, is/are based on phosphide compound semiconductor material. In this example the semiconductor chip may be configured such that only the quantum layers formed to generate radiation are based on arsenide compound semiconductor material, while the other semiconductor layers of the semiconductor chip are completely or at least partly based on phosphide compound semiconductor material. The arsenic content in the semiconductor body may in this way be reduced to a greater extent.

Preferably at most 25%, particularly preferably at most 15%, most preferably at most 5% of the group V lattice sites of the entire semiconductor body are occupied by arsenic. In particular, at most 1% of the group V lattice sites of the entire semiconductor body may be occupied by arsenic.

Preferably, a growth substrate for the preferably epitaxial deposition of the semiconductor layer sequence of the semiconductor body may be removed completely or at least in places. Such a semiconductor chip is also known as a thin film semiconductor chip. Gallium arsenide is particularly suitable as the growth substrate for arsenide compound semiconductor material. By removing the growth substrate the arsenic content of the semiconductor chip may be reduced.

Preferably, the semiconductor body is arranged on a carrier different from the growth substrate and which mechanically stabilizes the semiconductor layer sequence. The carrier may, for example, contain a semiconductor material, for instance germanium or silicon or consist of such a material. Alternatively or additionally, the carrier may also contain an electrically insulating material, for instance a ceramic, for example, aluminium nitride or boron nitride, or consist of such a material. A metal, for example, molybdenum or nickel, may also be used. It is additionally preferred for the carrier to be a part of the semiconductor chip. When producing the semiconductor chip, the carrier may be obtained on singulation from the wafer assembly.

Further preferably, a metallic mirror layer is arranged between the semiconductor body and the carrier. Radiation generated in the active region and emitted in the direction of the carrier may be reflected at the mirror layer and then exit from a major face of the semiconductor body opposite the carrier. The mirror layer may contain gold, for example. Gold is distinguished in the infrared spectral range by particularly high reflectivity. Alternatively, other materials may also be used for the mirror layer, for example, aluminium, silver, rhodium, palladium, nickel or chromium or a metal alloy with at least one of the stated metals.

We found that a comparatively large proportion of the semiconductor material of the semiconductor body with an active region based on arsenide compound semiconductor material may be constructed on the basis of phosphide compound semiconductor without impairing crystal quality. The arsenic content of the semiconductor chip preferably amounts overall to at most 0.5%, particularly preferably at most 0.1%.

We furthermore found that greater temperature stability may be achieved by barrier regions based on phosphide compound semiconductor material, in particular based on arsenic-free or substantially arsenic-free compound semiconductor material.

Further features, configurations and convenient aspects are revealed by the following description of the examples in conjunction with the figures.

Identical, similar or identically acting elements are provided with the same reference numerals in the figures.

The figures and the size ratios of the elements illustrated in the figures relative to one another are not to be regarded as being to scale. Rather, individual elements may be illustrated on an exaggeratedly large scale for greater ease of depiction and/or better comprehension.

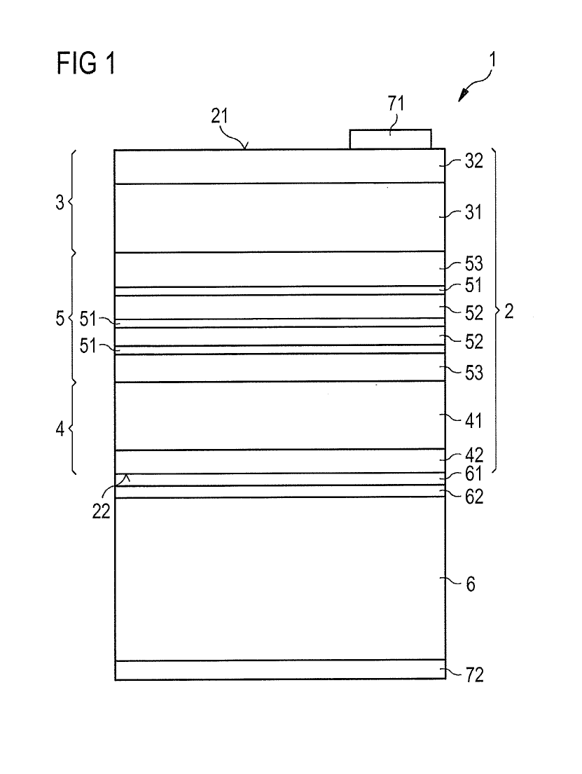

FIG. 1 shows a schematic sectional view of one example of a radiation-emitting semiconductor chip 1. The semiconductor chip comprises a semiconductor body 2 with a semiconductor layer sequence which forms the semiconductor body. The semiconductor layer sequence 2 is preferably deposited epitaxially on a growth substrate, for example, gallium arsenide. The semiconductor chip 1 further comprises a carrier 6 on which the semiconductor body 2 is arranged. The carrier and semiconductor body are mechanically joined together stably by a bonding layer 62. Materials suitable for the bonding layer if an electrically conductive bond is to be produced between the carrier 6 and the semiconductor body 2 are solder or an electrically conductive adhesive layer.

A metallic mirror layer 61 is arranged between the semiconductor body 2 and the carrier 6. The mirror layer is intended to reflect radiation generated in the active region when in operation and emitted in the direction of the carrier 6. In the infrared spectral range gold is particularly suitable for the mirror layer. In contrast thereto, however, one of the materials mentioned herein for the mirror layer may also be used.

The semiconductor layer sequence 2 comprises an active region 5 that generates radiation. The active region 5 is arranged between a first region of a first conduction type 3 and a second region of a second conduction type 4 different from the first conduction type. For example, the first region 3 may be p-conductive and the second sub-region n-conductive or vice versa.

In a vertical direction extending perpendicular to a main plane of extension of the semiconductor layers of the semiconductor layer sequence of the semiconductor body 2, the semiconductor body 2 extends between a first major face 21 and a second major face 22.

The active region 5 comprises a plurality of quantum layers 51, between which a barrier layer 52 is in each case arranged. A spacer layer 53 adjoins the outermost quantum layer on each side of the active region. The spacer layers 53 and the barrier layers 52 may be of identical construction or may differ from one another in terms of thickness and/or material composition. To simplify the representation, only three quantum layers are shown. The semiconductor body preferably comprises 3 to 20 quantum layers, particularly preferably five to 15 quantum layers. In contrast thereto, however, the active region may also comprise just one quantum layer.

The active region 5 is preferably undoped or intrinsically doped.

The first region 3 comprises a barrier layer 31 adjacent the active region 5. The first barrier layer 31 preferably comprises a larger band gap than the semiconductor layers of the active region 5 and moreover, preferably forms a charge carrier barrier. In the case of a p-conductive configuration of the first region 3, the charge carrier barrier takes the form of an electron barrier. The first region 3 comprises a first contact region 32 on the side of the first barrier layer 31 remote from the active region 5. The first contact region 32 is preferably formed by a material to which ohmic contact may be readily achieved with a first contact 71 provided for external electrical contacting.

Like the first region 3, the second region 4 comprises a second barrier region 41 and a second contact region 42.

A second contact 72 is provided on the side of the carrier 6 remote from the semiconductor body 2. By applying an electrical voltage between the first contact and the second contact, charge carriers are injected from different sides into the active region 5 and may recombine there with the emission of radiation. The contacts 71, 72 are arranged outside the epitaxial semiconductor body 2 and preferably contain a metal, for example, gold, silver, platinum, titanium, nickel, aluminium or rhodium or a metal alloy with at least one of the stated materials.

The arrangement and configuration of the contacts 71, 72 may be freely selected within broad ranges, provided that charge carriers can be injected into the active region from different sides via the contacts. The contacts 71, 72 may, for example, be arranged on the side of the semiconductor body 2 remote from the carrier 6. The carrier may in this case also be formed to be electrically insulating, for example, using a ceramic such as aluminium nitride or boron nitride. Furthermore, both contacts may also be arranged on the side of the carrier remote from the semiconductor body 2. Vias may, for example, be formed in the carrier through which the contacts electrically conductively connect to the semiconductor body.

The multilayer structure described is shown in simplified form for greater ease of depiction. The individual regions may themselves each be of single- or indeed multi-layer construction.

The active region 5 is preferably intended to generate radiation in the infrared spectral range, in particular in the wavelength range of 700 nm to 1500 nm.

The material composition of the semiconductor body 2 is described below with reference to three examples, wherein the above-described structure illustrated in FIG. 1 may be used in each case.

The active region 5, i.e. the quantum layers 51 and the barrier layers 52, is based on an arsenide compound semiconductor material. The emission wavelength can be adjusted by way of the material composition of the quantum layers. For example, with quantum layers with an aluminium content of 7%, a gallium content of 81% and an indium content of 12% and arsenic as the sole group V material, an emission wavelength of 810 nm may be achieved.

In this example, the thickness of the quantum layers amounts to approx. 4.6 nm. For a structure having a total of 12 quantum layers the total thickness of the active region 5 amounts to approx. 500 nm.

The thickness of the active region may vary, in particular as a function of the number of quantum layers and the emission wavelength. In particular, the thickness may amount to 3 nm to 1 μm. With one quantum layer the thickness may, for example, amount to 5 nm. For a plurality of quantum layers the thickness of the active region preferably amounts to 50 nm to 500 nm, particularly preferably 200 nm to 500 nm.

The first barrier region 31 and the second barrier region 41 each take the form of arsenic-free semiconductor layers based on phosphide compound semiconductor material.

The semiconductor layers of the semiconductor layer sequence based on phosphide compound semiconductor material preferably have an indium content of 45% to 60%, particularly preferably 50% to 56%. Lattice matching relative to arsenide compound semiconductor material may thus be achieved in simplified manner.

In this example, the contact regions 32, 42 take the form of arsenide compound semiconductor material regions, for example, based on AlₓIn_{y}Ga_{1-x-y}As with 0≦x≦1, 0≦y≦1, x+y≦1.

In particular, the arsenide compound semiconductor material of the contact regions 32, 42 may be indium-free or substantially indium-free. The semiconductor material directly adjoining the first major face 21 or the second major face 22 is preferably GaAs. A good electrical connection with ohmic characteristics to the first contact 71 or to the mirror layer 61 may thus be simply achieved.

The barrier layers 31, 41 are preferably significantly thicker than the contact regions 32, 42, preferably at least twice as thick, particularly preferably at least five times as thick as the associated contact regions. Even if an arsenide compound semiconductor material is used for the contact region, the first region 3 and the second region 4 are thus at least half based on phosphide compound semiconductor material relative to the respective vertical extent. Thus, even with contact regions 32, 42 with arsenic as the sole group V material, the semiconductor chip may overall have a comparatively low arsenic content.

For example, in the case of a total thickness of the semiconductor body 2 of 6 μm with a thickness of the active region of 500 nm, a total thickness of the two contact regions 32, 42 of 500 nm overall and an arsenic-free configuration of the barrier regions 31, 42, the arsenic content amounts to approximately a sixth relative to the number of group V sites and thus a twelfth of the lattice sites of the semiconductor body 2 overall. With an arsenic-free carrier 6, which is typically significantly thicker than the semiconductor body 2, having a thickness, for example, of 50 μm to 200 μm, the arsenic content in the semiconductor chip may be reduced overall to markedly below 5%, preferably to 1% or less.

In contrast thereto, in the case of a conventional semiconductor chip based on arsenide compound semiconductor material in which the growth substrate has not been removed, all the group V lattice sites of the semiconductor body and of the carrier are occupied by arsenic such that the semiconductor material of the semiconductor chip would consist overall of approximately 50% arsenic.

Unlike in the described configuration, the phosphide compound semiconductor material does not necessarily have to be arsenic-free. To reduce the arsenic content as much as possible, occupation of the group V sites with arsenic, i.e. the arsenic content z is preferably at most 30%, preferably at most 10%, most preferably at most 5%.

The material composition and thickness of the barrier regions 31, 41 and the contact regions 32, 42 is preferably such that at most 20% of the group V lattice sites of the entire first region and/or at most 20% of the group V lattice sites of the entire second region are occupied by arsenic.

Unlike in the described configuration, it is also possible for just one of the barrier regions 31, 32 to be based on a phosphide compound semiconductor material. The number of transitions between arsenide compound semiconductor material and phosphide compound semiconductor material during epitaxial deposition of the semiconductor layer sequence of the semiconductor body 2 can be reduced thereby. For the most extensive possible reduction of the arsenic content, however, it is preferable for both barrier regions to be arsenic-free or at least substantially arsenic-free.

In a second example of the material composition of the semiconductor body 2 the semiconductor layers are embodied substantially as described in relation to the first example.

At variance therewith, the contact regions 32, 42 are likewise based on phosphide compound semiconductor material. In this case, therefore, the entire first region and entire second region are based on phosphide compound semiconductor material. In particular, both regions may be arsenic-free. The arsenic content may thus be reduced to an even greater extent.

In a third example of a material composition, the first region 3 and second region 4 may be embodied as described in relation to the first or second examples. Unlike in these examples, the barrier layers 52 of the active region 5 are also based on phosphide compound semiconductor material. In this case, therefore, only the quantum layers 51 of the active region are based on arsenide compound semiconductor material.

In this case, therefore, the quantum layers may be the only layers of the semiconductor body 2 which are based on arsenide compound semiconductor material. In the case of 12 quantum layers each with a thickness of 5 nm and a total thickness of the semiconductor body 2 of 6 μm, the arsenic occupation of the group V lattice sites of the semiconductor body 2 may be reduced overall to approx. 1% and thus the arsenic content of the semiconductor body overall to approx. 0.5%.

The arsenic content of the semiconductor chip may thus be reduced to below 0.1% even for a carrier thickness of 25 μm.

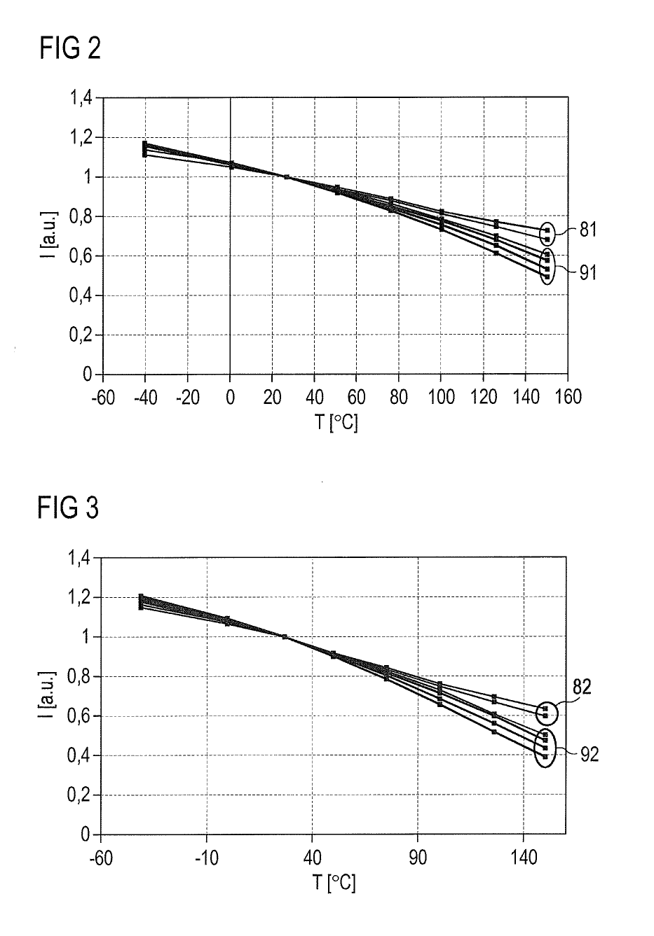

FIGS. 2 and 3 each show the intensity of the radiation generated when in operation normalised to the value at room temperature for semiconductor chips with phosphide barrier regions and an emission wavelength of 810 nm. This is illustrated by the curves 81 and 82 respectively, as a function of the temperature of the semiconductor chips. In comparison, the curves 91 and 92 respectively show measurements on conventional semiconductor chips based on arsenide compound semiconductor material. The measurements were taken at a current of 70 mA (FIGS. 2) and 200 mA (FIG. 3), the semiconductor chips being mounted without potting in a TO18 package. Current was supplied in each case in pulses of a duration of 20 ms.

For both current values the curves with barrier regions based on phosphide compound semiconductor material have a flatter profile, such that the intensity decreases more slowly at higher temperatures than in the case of the comparison samples.

The measurements thus prove that the described semiconductor chip configuration brings about improved temperature stability with simultaneous improvement of environmental compatibility.

Our chips are not restricted by the description given with reference to the examples. Rather, this disclosure encompasses any novel feature and any combination of features, including in particular any combination of features in the appended claims, even if the feature or combination is not itself explicitly indicated in the claims or examples.

1.-15. (canceled)

16. A radiation-emitting semiconductor chip comprising a semiconductor body with a semiconductor layer sequence, wherein
the semiconductor body with the semiconductor layer sequence extends in a vertical direction between a first major face and a second major face;
the semiconductor layer sequence comprises an active region that generates radiation, a first region of a first conduction type and a second region of a second conduction type differing from the first conduction type;
the first region extends in a vertical direction between the first major face and the active region;
the second region extends in a vertical direction between the second major face and the active region;
at least one layer of the active region is based on an arsenide compound semiconductor material; and
relative to its respective extent in the vertical direction, the first region or the second region is based in a proportion of at least half on a phosphide compound semiconductor material.

17. The radiation-emitting semiconductor chip according to claim 16, wherein, relative to their respective extent in the vertical direction, the first region and the second region are based in a proportion of at least half on a phosphide compound semiconductor material.

18. The radiation-emitting semiconductor chip according to claim 16, wherein the phosphide compound semiconductor material is formed by the material system InₓAl_{y}Ga_{1-x-y}P_{1-z}As_{z} with 0≦x≦0.6, 0≦y≦1, x+y≦1 and 0≦z≦0.3.

19. The radiation-emitting semiconductor chip according to claim 18, wherein 0.45≦x≦0.6 applies.

20. The radiation-emitting semiconductor chip according to claim 18, wherein 0≦z≦0.05 applies.

21. The radiation-emitting semiconductor chip according to claim 16, wherein at most 20% of the group V lattice sites of the entire first region and/or at most 20% of the group V lattice sites of the entire second region are occupied by arsenic.

22. The radiation-emitting semiconductor chip according to claim 16, wherein the first region comprises a contact region adjoining the first major face and a barrier region between the contact region and the active region and at most 10% the group V lattice sites of the barrier region are occupied by arsenic.

23. The radiation-emitting semiconductor chip according to claim 16, wherein the first barrier region is free of arsenic.

24. The radiation-emitting semiconductor chip according to claim 16, wherein the active region comprises a quantum well structure with at least one quantum layer and at least one barrier layer.

25. The radiation-emitting semiconductor chip according to claim 16, wherein at least one barrier layer of the quantum well structure is based on phosphide compound semiconductor material.

26. The radiation-emitting semiconductor chip according to claim 16, wherein at most 15% of the group V lattice sites of the semiconductor body are occupied by arsenic.

27. The radiation-emitting semiconductor chip according to claim 16, wherein the entire first region and/or the entire second region is/are based on phosphide compound semiconductor material.

28. The radiation-emitting semiconductor chip according to claim 16, wherein a growth substrate for the semiconductor layer sequence of the semiconductor body is removed completely or at least in places.

29. The radiation-emitting semiconductor chip according to claim 16, wherein the semiconductor body is arranged on a carrier which mechanically stabilizes the semiconductor layer sequence and a metallic mirror layer is arranged between the semiconductor body and the carrier.

30. The radiation-emitting semiconductor chip according to claim 16, wherein
relative to their respective extent in the vertical direction, the first region and the second region are based in a proportion of at least half on a phosphide compound semiconductor material; and
the phosphide compound semiconductor material is formed by the material system InₓAl_{y}Ga_{1-x-y}P_{1-z}As_{z} with 0.45≦x≦0.6, 0≦y≦0.55, x+y≦1 and 0≦z≦0.05.

31. A radiation-emitting semiconductor chip comprising a semiconductor body with a semiconductor layer sequence, wherein
the semiconductor body with the semiconductor layer sequence extends in a vertical direction between a first major face and a second major face;
the semiconductor layer sequence comprises an active region that generates radiation, a first region of a first conduction type and a second region of a second conduction type differing from the first conduction type;
the first region extends in a vertical direction between the first major face and the active region;
the second region extends in a vertical direction between the second major face and the active region;
at least one layer of the active region is based on an arsenide compound semiconductor material; and
the entire first region and the entire second region are based on phosphide compound semiconductor material.
